(19) United States
(12) Patent Application Publication
(10) Pub. No.: US 2026/0068698 A1
(43) Pub. Date: Mar. 5, 2026

(54) SEMICONDUCTOR DEVICE

(71) Applicant: Kioxia Corporation, Tokyo (JP)

(72) Inventor: Toshikazu SAKAIRI, Yokkaichi Mie (JP)

(21) Appl. No.: 19/073,682

(22) Filed: Mar. 7, 2025

(30) Foreign Application Priority Data
Sep. 5, 2024 (JP) 2024-153212

(51) Int. Cl. H01L 23/538; H01L 23/00; H01L 25/18; H10B 80/00; H10D 80/30

(52) U.S. Cl. CPC H01L 23/5383; H10B 80/00; H10D 80/30

(57) ABSTRACT

A semiconductor device includes a substrate having a first outer surface, a second outer surface opposite to the first outer surface, at least first, second, and third conductive layers, a plurality of insulating layers, and a plurality of vias. The first conductive layer includes a pad having an outer surface that is exposed on the first outer surface, and the second conductive layer includes a terminal electrically connected to the pad through at least one of the vias, a wire electrically connected to the terminal, and a first mesh electrically and physically separated from the terminal and the wire. A second mesh is included in the first conductive layer or the third conductive layer that is between the first conductive layer and the second conductive layer, is electrically isolated from the pad, the terminal, and the wire, and covers the terminal, the wire, and the first mesh.

### CROSS-REFERENCE TO RELATED APPLICATIONS

This application is based upon and claims the benefit of priority from Japanese Patent Application No. 2024-153212, filed Sep. 5, 2024, the entire contents of which are incorporated herein by reference.

### FIELD

Embodiments described herein relate generally to a semiconductor device.

### BACKGROUND

Some semiconductor devices include a substrate provided with pads. Such a semiconductor device is connected to another device with, for example, solder provided on the pads. The substrate includes, for example, a plurality of conductive layers, insulating layers each being interposed between adjacent two of the plurality of conductive layers, and vias each connecting at least two of the plurality of conductive layers.

Inside the substrate, the difference in thermal expansion between the conductive layers and the insulating layers may cause stresses (in particular, thermal stresses) at the juncture of the edge of a pattern in one of the conductive layers and one of the insulating layers. The thermal stress is likely to cause a crack at the juncture of the edge of the pattern in the conductive layer and the insulating layer.

### BRIEF DESCRIPTION OF THE DRAWINGS

FIG. 1 is an exemplary sectional view schematically illustrating a semiconductor device according to a first embodiment.

FIG. 2 is an exemplary sectional view schematically illustrating a part of the semiconductor device of the first embodiment.

FIG. 3 is an exemplary plan view schematically illustrating three conductive layers in the semiconductor device of the first embodiment.

FIG. 4 is an exemplary sectional view schematically illustrating a conductive layer formed on a glass substrate in the semiconductor device of the first embodiment.

FIG. 5 is an exemplary sectional view schematically illustrating an insulating layer formed on the conductive layer in the semiconductor device of the first embodiment.

FIG. 6 is an exemplary sectional view schematically illustrating a conductive layer formed on the insulating layer in the semiconductor device of the first embodiment.

FIG. 7 is an exemplary sectional view schematically illustrating an interposer formed on the glass substrate in the semiconductor device of the first embodiment.

FIG. 8 is an exemplary sectional view schematically illustrating the interposers sealed with sealing resin in the semiconductor device of the first embodiment.

FIG. 9 is an exemplary sectional view schematically illustrating a semiconductor device of the first embodiment that is to be diced.

FIG. 10 is an exemplary plan view schematically illustrating three conductive layers according to a first modification of the first embodiment.

FIG. 11 is an exemplary plan view schematically illustrating three conductive layers according to a second modification of the first embodiment.

FIG. 12 is an exemplary plan view schematically illustrating three conductive layers according to a third modification of the first embodiment.

FIG. 13 is an exemplary sectional view schematically illustrating a part of a semiconductor device according to a second embodiment.

FIG. 14 is an exemplary sectional view schematically illustrating a part of a semiconductor device according to a modification of the second embodiment.

FIG. 15 is an exemplary plan view schematically illustrating three conductive layers according to a third embodiment.

FIG. 16 is an exemplary sectional view schematically illustrating a part of a semiconductor device according to a fourth embodiment.

### DETAILED DESCRIPTION

Embodiments provide a semiconductor device that can suppress a crack from being caused by a thermal stress.

In general, according to one embodiment, a semiconductor device according to one embodiment includes a substrate. The substrate includes a first outer surface, a second outer surface located on an opposite side of the substrate with respect to the first outer surface, and a pad provided on the first outer surface. The substrate includes four or five conductive layers, a plurality of insulating layers each interposed between adjacent two of the conductive layers, and a plurality of vias each connecting at least two of the conductive layers. A distance between the first outer surface and the second outer surface is 50 μm or smaller in a case where a number of the conductive layers is four, and the distance between the first outer surface and the second outer surface is 60 μm or smaller in a case where the number of the conductive layers is five. The conductive layers include the pad, a terminal, a wire, a first mesh, and a second mesh. The pad is included in a first conductive layer of the conductive layers. The terminal is included in a second conductive layer of the conductive layers and is electrically connected to the pad through at least one of the vias. The wire is included in the second conductive layer and is electrically connected to the terminal. The first mesh is included in the second conductive layer and is electrically and physically separated from the terminal and the wire. The second mesh is included in the first conductive layer or a third conductive layer of the conductive layers between the first conductive layer and the second conductive layer and is electrically isolated from the pad, the terminal, and the wire. With the second mesh, the terminal, the wire, and the first mesh are each covered at least partially when viewed in a direction perpendicular to the first outer surface.

### First Embodiment

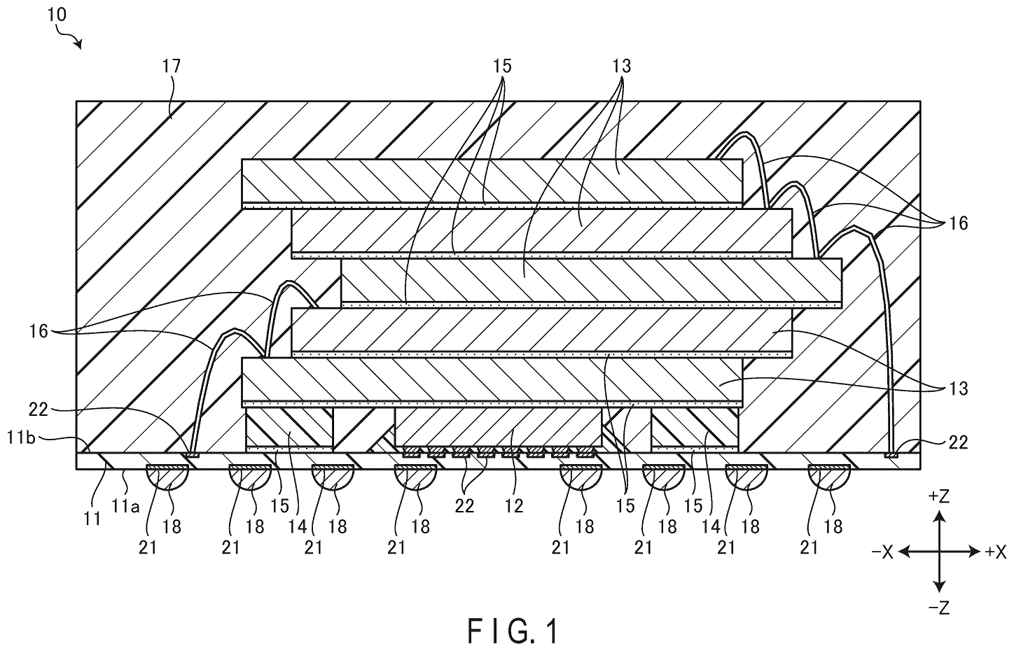

With reference to FIG. 1 to FIG. 12, a first embodiment will be described below. In the present description, the same constituent elements according to embodiments and the description thereof may be described in multiple expressions. The constituent elements and the description thereof are merely examples and are not limited to the expressions in the present description. The constituent elements can be specified with names different from those used in the present description. Furthermore, the constituent elements can be described in expressions different from those used in the present description.

In the following description, the verb “suppress” is defined as, for example, preventing the occurrence of an event, an action, or an impact or reducing the degree of the event, the action or the impact.

FIG. 1 is an exemplary sectional view schematically illustrating a semiconductor device 10 according to the first embodiment. An example of the semiconductor device 10 in the present embodiment is, for example, universal flash storage (UFS) or an embedded memory based on another standard. The semiconductor device 10 in the present embodiment can be referred to as, for example, a semiconductor memory device, a package, or an electronic component. Note that the semiconductor device may be another type of memory such as dynamic random access memory (DRAM) or may be another type of semiconductor device such as a central processing unit (CPU).

As illustrated in each figure, an X direction (a +X direction and a −X direction), a Y direction (a +Y direction and a −Y direction), and a Z direction (a +Z direction and a −Z direction) are herein defined. The X direction, the Y direction, and the Z direction are perpendicular to one another. The X direction is a direction along the width of the semiconductor device 10, and the +X direction and the −X direction are opposite to each other. The Y direction is a direction along the depth of the semiconductor device 10, and the +Y direction and the −Y direction are opposite to each other. The Z direction is a direction along the thickness of the semiconductor device 10, and the +Z direction and the −Z direction are opposite to each other.

As illustrated in FIG. 1, the semiconductor device 10 includes an interposer 11, a memory controller 12, a plurality of flash memories 13, a plurality of spacers 14, a plurality of bonding films 15, a plurality of bonding wires 16, sealing resin 17, and a plurality of bumps 18. The interposer 11 is an example of a substrate. Note that the substrate is not limited to the interposer. The substrate may be another type of substrate. The memory controller 12 and the flash memories 13 can each be referred to as a semiconductor chip.

The interposer 11 in the present embodiment is, for example, an organic substrate that is manufactured by using redistribution layer (RDL) technology. As a result, the interposer 11 can be formed to be thin. Hereinafter, the organic substrate manufactured by using the RDL technology will be called an RDL substrate. Note that the interposer 11 is not limited to an RDL substrate.

The interposer 11 includes two outer surfaces 11a and 11b. The outer surface 11a is an example of a first outer surface. The outer surface 11b is an example of a second outer surface. The two outer surfaces 11a and 11b can each be referred to as a principal surface. The two outer surfaces 11a and 11b are each formed in a substantially quadrilateral shape that is disposed along an X-Y plane. The outer surface 11a faces substantially in the −Z direction. The outer surface 11b is located on the opposite side to the outer surface 11a and faces substantially in the +Z direction.

The interposer 11 further includes a plurality of pads 21 and 22. The plurality of pads 21 are provided on the outer surface 11a. The plurality of pads 21 are arranged in, for example, a grid pattern. The plurality of pads 22 are provided on the outer surface 11b.

The memory controller 12 is mounted on the outer surface 11b of the interposer 11 by, for example, flip chip mounting. That is, a plurality of bumps of the memory controller 12 are connected to the plurality of pads 22. Note that the memory controller 12 may be mounted on the interposer 11 by another mounting method.

The plurality of flash memories 13 are stacked in the Z direction on the memory controller 12. That is, the memory controller 12 is located between the interposer 11 and the plurality of stacked flash memories 13.

Each of the spacers 14 is, for example, a silicon member having surfaces to which a resin that is an insulator such as polyimide is applied. Note that the spacers 14 may be made of silicon, polyimide, or another material. Note that the material of the spacers 14 is not limited to this example. The plurality of spacers 14 are located between the interposer 11 and the plurality of stacked flash memories 13.

Every two adjacent flash memories 13 of the plurality of flash memories 13 are bonded together with one of the bonding films 15. In addition, one of the plurality of flash memories 13 that is closest to the interposer 11 is bonded to the memory controller 12 and the plurality of spacers 14 with a bonding film 15. Each of the plurality of spacers 14 is bonded to the outer surface 11b of the interposer 11 with some of the bonding films 15.

Every two adjacent flash memories 13 of the plurality of flash memories 13 are offset from each other in a direction perpendicular to the Z direction. The plurality of flash memories 13 are connected to the interposer 11 by wire bonding. That is, electrodes of each of the plurality of flash memories 13 are connected to electrodes of another flash memory 13 or the pads 22 of the interposer 11 via the bonding wires 16.

The sealing resin 17 seals the memory controller 12, the flash memories 13, the spacers 14, the bonding films 15, and the bonding wires 16. That is, the sealing resin 17 adheres to the outer surface 11b of the interposer 11, and the memory controller 12, the flash memories 13, the spacers 14, the bonding films 15, and the bonding wires 16 are embedded in the sealing resin 17.

The bumps 18 are made of, for example, solder. Each of the plurality of bumps 18 is provided at a corresponding one of the plurality of pads 21. Through the bumps 18, the plurality of pads 21 of the semiconductor device 10 are connected to, for example, pads of another or other substrates.

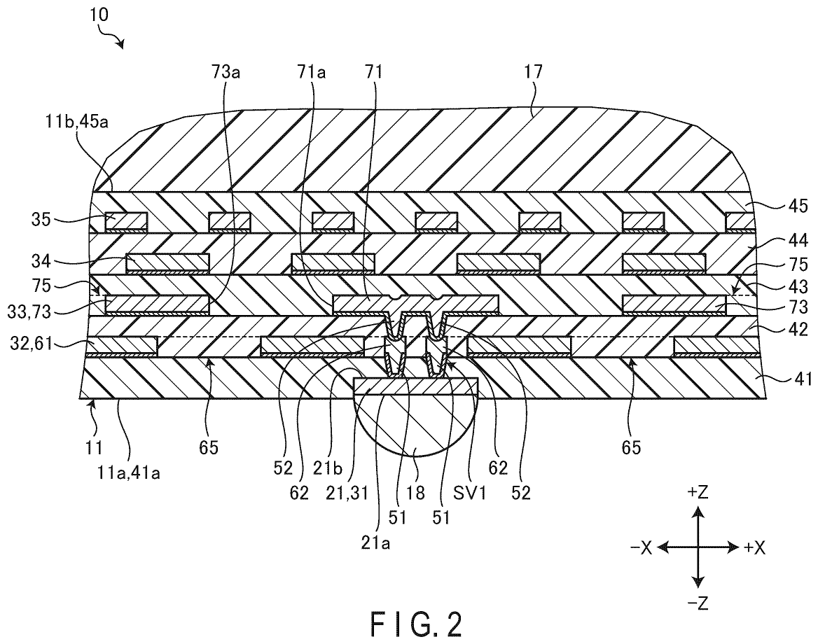

FIG. 2 is an exemplary sectional view schematically illustrating a part of the semiconductor device 10 in the first embodiment. As illustrated in FIG. 2, the interposer 11 in the present embodiment includes five conductive layers 31, 32, 33, 34, and 35, five insulating layers 41, 42, 43, 44, and 45, and pluralities of vias 51 and 52. The conductive layer 31 is an example of a first conductive layer. The conductive layer 32 is an example of a third conductive layer. The conductive layer 33 is an example of a second conductive layer. The via 51 is an example of a first via. The via 52 is an example of a second via.

The conductive layers 31, 32, 33, 34, and 35 and the vias 51 and 52 are each made of metals. For example, each of the conductive layers 31, 32, 33, 34, and 35 and the vias 51 and 52 includes a titanium (Ti) film and a copper (Cu) film that is formed on the titanium film by electrolytic plating. Note that the material and the manufacturing method of the conductive layers 31, 32, 33, 34, and 35 and the vias 51 and 52 are not limited to this example.

The insulating layers 41, 42, 43, 44, and 45 are made of an insulating organic material (such as a dielectric material). For example, the insulating layers 41, 42, 43, 44, and 45 are made of polyimide (PI). Note that the material of the insulating layers 41, 42, 43, 44, and 45 is not limited to this example.

The plurality of conductive layers 31, 32, 33, 34, and 35 are stacked such that they are separated from each other in the Z direction. The insulating layer 41 is interposed between two conductive layers 31 and 32. The insulating layer 42 is interposed between two conductive layers 32 and 33. The insulating layer 43 is interposed between two conductive layers 33 and 34. The insulating layer 44 is interposed between two conductive layers 34 and 35. The insulating layer 45 covers the conductive layer 35 and the insulating layer 44.

The conductive layer 31 includes the plurality of pads 21. Note that the conductive layer 31 may have another pattern. The plurality of pads 21 each include two flat surfaces 21a and 21b. The flat surfaces 21a and 21b are each formed in a substantially circular shape.

The flat surface 21a forms a part of the outer surface 11a. That is, the flat surface 21a is included in the outer surface 11a. The flat surface 21a faces substantially in the −Z direction. The insulating layers 41, 42, 43, 44, and 45 of the interposer 11 in the present embodiment do not cover the flat surface 21a. That is, the flat surface 21a is separated from the insulating layers 41, 42, 43, 44, and 45. The flat surface 21b is located on the opposite side to the flat surface 21a and faces substantially in the +Z direction. The flat surface 21b is covered by the insulating layer 41.

The conductive layer 32 includes a mesh 61 and a plurality of relay patterns 62. That is, the mesh 61 is included in the conductive layer 32 located between the two conductive layers 31 and 33. The mesh 61 is an example of a second mesh.

The mesh 61 is provided with a plurality of holes 65. The plurality of holes 65 penetrate the mesh 61 in the Z direction. For example, the plurality of holes 65 have substantially the same shape and are separated from each other. Note that the plurality of holes 65 may have different shapes. The holes 65 are each, for example, a circular hole. Note that the holes 65 may each be formed in another shape.

The plurality of relay patterns 62 are each located in one of the plurality of holes 65 of the mesh 61. In the present embodiment, four of the plurality of relay patterns 62 are located in one of the plurality of holes 65. Note that the number of relay patterns 62 located in a hole 65 is not limited to this example.

The plurality of relay patterns 62 are separated from each other and are separated from the mesh 61. The relay patterns 62 are electrically isolated from the mesh 61. In one hole 65, at least two of the plurality of relay patterns 62 may be connected to each other.

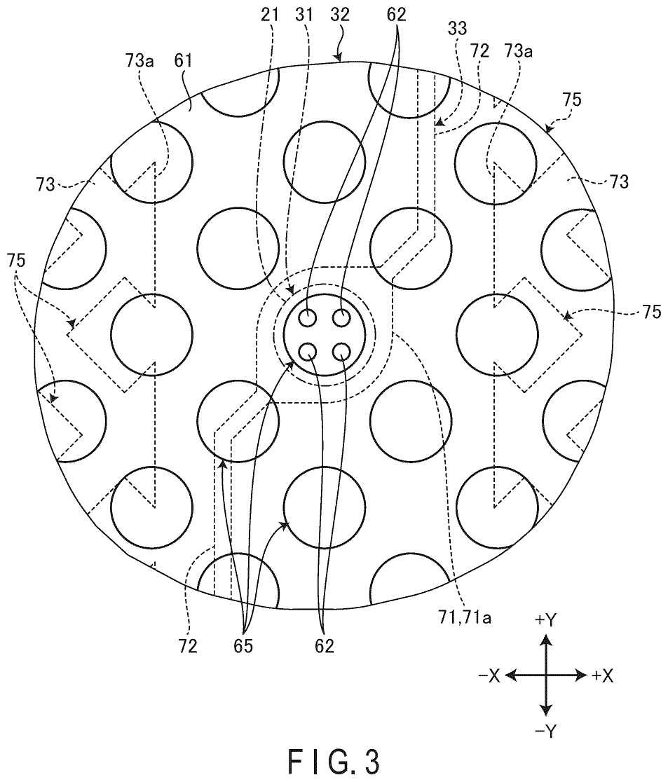

FIG. 3 is an exemplary plan view schematically illustrating three conductive layers 31, 32, and 33 in the first embodiment. FIG. 3 illustrates the conductive layer 31 with a two-dot-dash line, the conductive layer 32 with a solid line, and the conductive layer 33 with a broken line. The conductive layer 33 includes a plurality of terminals 71, a plurality of wires 72, and a plurality of meshes 73. The meshes 73 are an example of first meshes. FIG. 3 illustrates one of the plurality of terminals 71. The number of the plurality of terminals 71 is equal to the number of the plurality of pads 21.

The plurality of terminals 71 are each formed in a substantially quadrilateral shape. Note that the terminals 71 may each be formed in another shape such as a circular shape. Each of the plurality of terminals 71 is connected to at least one of the plurality of wires 72. For example, the wires 72 are connected to the corners of the terminals 71.

The plurality of meshes 73 are each separated from the terminals 71 and the wires 72. The plurality of meshes 73 are each provided with a plurality of holes 75. The plurality of holes 75 penetrate the meshes 73 in the Z direction. For example, the plurality of holes 75 have substantially the same shape and are separated from each other. Note that the plurality of holes 75 may have different shapes. Each of the holes 75 is, for example, a rhombic (rectangular or quadrilateral) hole. Note that the holes 75 may each be formed in another shape.

The conductive layers 34 and 35 illustrated in FIG. 2 each include, for example, a plurality of wires. The conductive layer 35 further includes, for example, the plurality of pads 22. As a result, the conductive layer 35 forms a part of the outer surface 11b of the interposer 11.

The insulating layer 41 includes a surface 41a. The surface 41a forms a part of the outer surface 11a together with flat surfaces 21a of the pads 21. The surface 41a is formed to be substantially flat and faces substantially in the −Z direction. In the present embodiment, the surface 41a of the insulating layer 41 projects in the −Z direction from the flat surfaces 21a of the pads 21. In other words, the flat surfaces 21a of the pads 21 are recessed from the surface 41a of the insulating layer 41.

The insulating layer 45 includes a surface 45a. The surface 45a forms a part of the outer surface 11b together with the pads 22. The surface 45a is formed to be substantially flat and faces substantially in the +Z direction.

The pluralities of vias 51 and 52 are, for example, filled vias. Note that the vias 51 and 52 may be vias of another type such as conformal vias.

The plurality of vias 51 penetrate the insulating layer 41 between the two conductive layers 31 and 32, connecting the two conductive layers 31 and 32. In the present embodiment, the plurality of vias 51 each connects one of the plurality of pads 21 and one of the plurality of relay patterns 62. The vias 51 are connected to the flat surfaces 21b of the pads 21.

The plurality of vias 52 penetrate the insulating layer 42 between the two conductive layers 32 and 33, connecting the two conductive layers 32 and 33. In the present embodiment, the plurality of vias 52 each connects one of the plurality of terminals 71 and one of the plurality of relay patterns 62.

One via 51 and one via 52 connected to one relay pattern 62 are disposed at substantially the same position in the X direction and the Y direction and extend in the Z direction. That is, the vias 51 and 52 and the relay patterns 62 form stack vias SV1. The stack vias SV1 may have another pattern. The Z direction is a direction perpendicular to the outer surface 11a.

Each of the plurality of terminals 71 is connected to one of the plurality of pads 21 through at least one via. In the present embodiment, each of the plurality of terminals 71 is connected to one pad 21 through four vias 51, four relay patterns 62, and four vias 52. Each of the numbers of vias 51, relay patterns 62, and vias 52 connected to one pad is not limited to four and may be two, three, five, or more than five. One terminal 71 may be connected to one pad 21 through one via 51, one relay pattern 62, and one via 52.

A plurality of the stack vias SV1 pass through the holes 65 of the mesh 61 and each extend between one of the plurality of pads 21 and one of the plurality of terminals 71. The stack vias SV1 are separated from the mesh 61.

The mesh 61 is electrically isolated from the plurality of pads 21, the plurality of terminals 71, and the plurality of wires 72. In the present embodiment, the mesh 61 is electrically floating or connected to the ground. The mesh 61 of the conductive layer 32 and the meshes 73 of the conductive layer 33 may be electrically connected to each other. For example, the meshes 61 and 73 may be connected to each other with vias.

In a projection in the Z direction perpendicular to the outer surface 11a, such as FIG. 3, each of the plurality of holes 65 of the mesh 61 is smaller than each of the plurality of terminals 71. For example, the diameter of the circular holes 65 is smaller than the width of the terminals 71. The mesh 61 covers the plurality of terminals 71, the plurality of wires 72, and the plurality of meshes 73 at least partially as viewed in the Z direction.

Specifically, the mesh 61 overlaps the edges 71a of the plurality of terminals 71, the plurality of wires 72, and the edges 73a of the plurality of meshes 73 at least partially as viewed in the Z direction. The edges 71a are the edges of the terminals 71 in a direction along the outer surface 11a. The edges 73a are the edges of the meshes 73 in the direction along the outer surface 11a. The mesh 61 covers the insulating layer 43 between the edges 71a of the terminals 71 and the edges 73a of the meshes 73.

In a projection in the Z direction, each of the plurality of holes 65 of the mesh 61 in the present embodiment is smaller than each of the plurality of pads 21. The mesh 61 covers the plurality of pads 21 at least partially as viewed in the Z direction. Note that the pads 21 need not be covered by the mesh 61.

The interposer 11 manufactured by using the RDL technology is thinner than a typical multilayer substrate. The interposer 11 in the present embodiment including the conductive layers 31, 32, 33, 34, and 35, the number of which is five, has a thickness of 60 μm or smaller. The thickness of the interposer 11 is the distance between the two outer surfaces 11a and 11b.

Note that the interposer 11 may include four conductive layers 31, 32, 33, and 35 and four insulating layers 41, 42, 43, and 45. That is, the conductive layer 34 and the insulating layer 44 may be omitted. In this case, the thickness of the interposer 11 is 50 μm or smaller.

By using the RDL technology, the interposer 11 can be manufactured with each of the conductive layers 31, 32, 33, 34, and 35 being made thin. The thickness of each of the conductive layers 31, 32, 33, 34, and 35 is 10 μm or smaller. An example of the thickness of each of the conductive layers 31, 32, 33, 34, and 35 is about 5 to 6 μm. In a typical multilayer substrate, the thickness of each conductive layer is, for example, about 20 to 35 μm.

By using the RDL technology, the interposer 11 can be manufactured with the width of the wires 72 being made small. The width of the wires 72 is smaller than 10 μm. An example of the width of the wires 72 is 5 to 6 μm. In a typical multilayer substrate, the width of each wire is, for example, 20 to 35 μm.

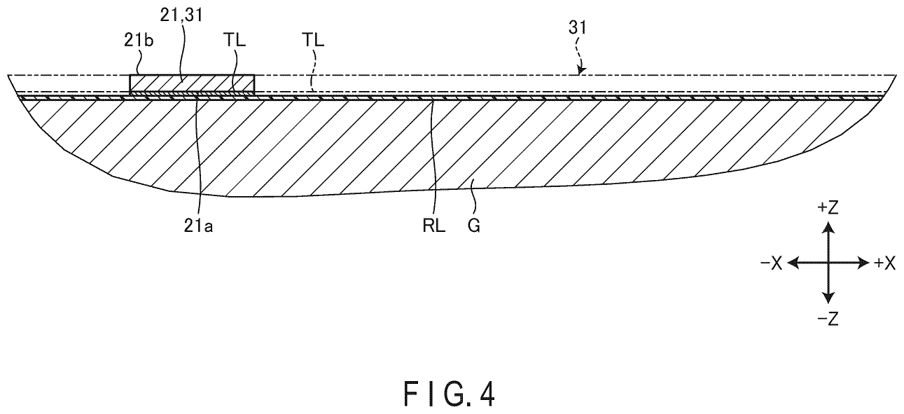

Hereinafter, with reference to FIG. 4 to FIG. 9, a part of a method for manufacturing the semiconductor device 10 will be described. Note that the method for manufacturing the semiconductor device 10 is not limited to the following method, and another method may be used. FIG. 4 is an exemplary sectional view schematically illustrating the conductive layer 31 formed on a glass substrate G in the first embodiment.

The interposer 11 is formed on the glass substrate G illustrated in FIG. 4. First, a release layer RL is applied to the glass substrate G. Next, a titanium layer TL is formed on the release layer RL. 15 As illustrated with a two-dot-dash line in FIG. 4, the titanium layer TL is formed on the entire top surface of the release layer RL.

Next, the conductive layer 31 as a copper foil is formed on the titanium layer TL by electrolytic plating. As illustrated with two-dot-dash lines in FIG. 4, the conductive layer 31 is formed on the entire top surface of the titanium layer TL. Next, the conductive layer 31 and the titanium layer TL are partially removed by photolithography, and thus the pads 21 of the conductive layer 31 are formed as illustrated in FIG. 4.

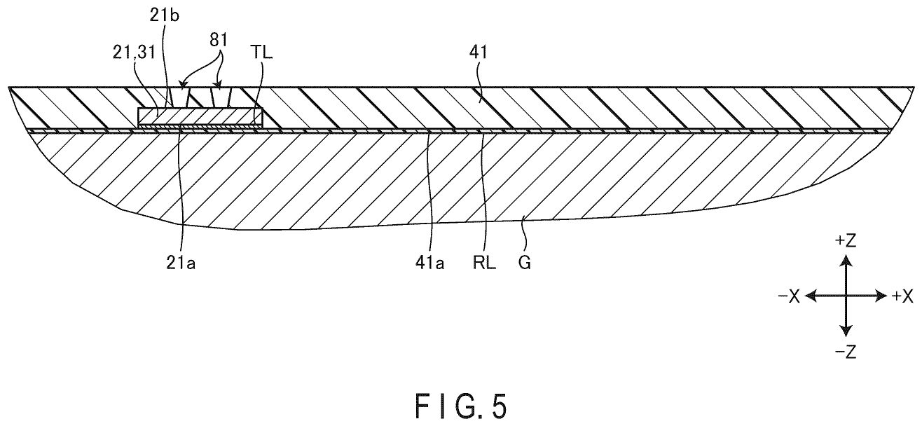

FIG. 5 is an exemplary sectional view schematically illustrating the insulating layer 41 formed on the conductive layer 31 in the first embodiment. Next, the insulating layer 41 is formed on the glass substrate G and the conductive layer 31. The thickness of the insulating layer 41 is larger than the thickness of the conductive layer 31. As a result, the insulating layer 41 covers the conductive layer 31.

Next, as illustrated in FIG. 4, a plurality of through holes 81 are formed in the insulating layer 41. The plurality of through holes 81 are formed in the insulating layer 41 by, for example, reactive ion etching (RIE). The plurality of through holes 81 penetrate the insulating layer 41 to expose the flat surfaces 21b of the pads 21.

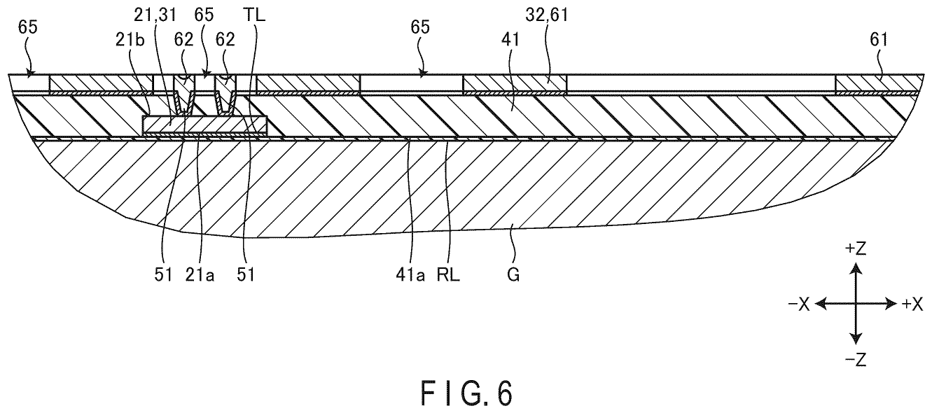

FIG. 6 is an exemplary sectional view schematically illustrating the conductive layer 32 formed on the insulating layer 41 in the first embodiment. Next, a titanium layer is formed on the insulating layer 41 and the flat surfaces 21b of the pads 21 that are exposed by the through holes 81.

Next, a copper foil is formed on the titanium layer by electrolytic plating. Thus, the conductive layer 32 and the plurality of vias 51 are formed. That is, the conductive layer 32 includes the titanium layer provided on the insulating layer 41 and the copper foil provided on the titanium layer. Each of the plurality of vias 51 includes the titanium layer provided on the flat surfaces 21b and the copper foil provided on the titanium layer. Parts of the titanium layer and the copper foil are drawn into the through holes 81. Next, the conductive layer 32 is partially removed by photolithography, and thus the mesh 61 and the plurality of relay patterns 62 of the conductive layer 32 are formed as illustrated in FIG. 6.

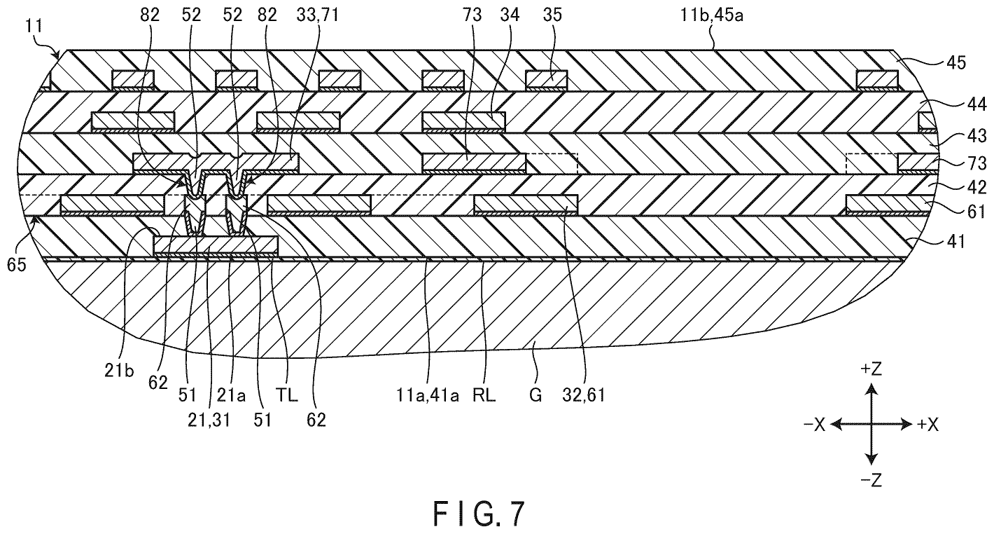

FIG. 7 is an exemplary sectional view schematically illustrating the interposer 11 formed on the glass substrate G in the first embodiment. Next, the insulating layer 42 is formed on the conductive layer 32 and the insulating layer 41. The thickness of the insulating layer 42 is larger than the thickness of the conductive layer 32. As a result, the insulating layer 42 covers the conductive layer 32. In addition, parts of the insulating layer 42 are drawn into the plurality of holes 65 of the mesh 61.

Next, as illustrated in FIG. 7, a plurality of through holes 82 are formed in the insulating layer 42. The plurality of through holes 82 are formed in the insulating layer 42 by, for example, RIE. The plurality of through holes 82 penetrate the insulating layer 42 to expose the relay patterns 62.

Next, a titanium layer is formed on the insulating layer 42 and the relay patterns 62 that are exposed by the through holes 82. Next, a copper foil is formed on the titanium layer by electrolytic plating. Thus, the conductive layer 33 and the plurality of vias 52 are formed. That is, the conductive layer 33 includes the titanium layer provided on the insulating layer 42 and the copper foil provided on the titanium layer. Each of the plurality of vias 52 includes the titanium layer provided on the relay patterns 62 and the copper foil provided on the titanium layer. Parts of the titanium layer and the copper foil are drawn into the through holes 82. Next, the conductive layer 33 is partially removed by photolithography, and thus the plurality of terminals 71, the plurality of wires 72, and the plurality of meshes 73 of the conductive layer 33 are formed as illustrated in FIG. 7.

As illustrated in FIG. 7, after the conductive layer 33 is formed, the insulating layer 43, the conductive layer 34, the insulating layer 44, the conductive layer 35, and the insulating layer 45 are sequentially formed. The conductive layers 34 and 35 each include a titanium layer and a copper foil as with the conductive layers 32 and 33 and are each subjected to photolithography to have a pattern. Thus, the plurality of pads 22 of the conductive layer 35 are formed. In the above manner, a plurality of interposers 11 are integrally formed on the glass substrate G.

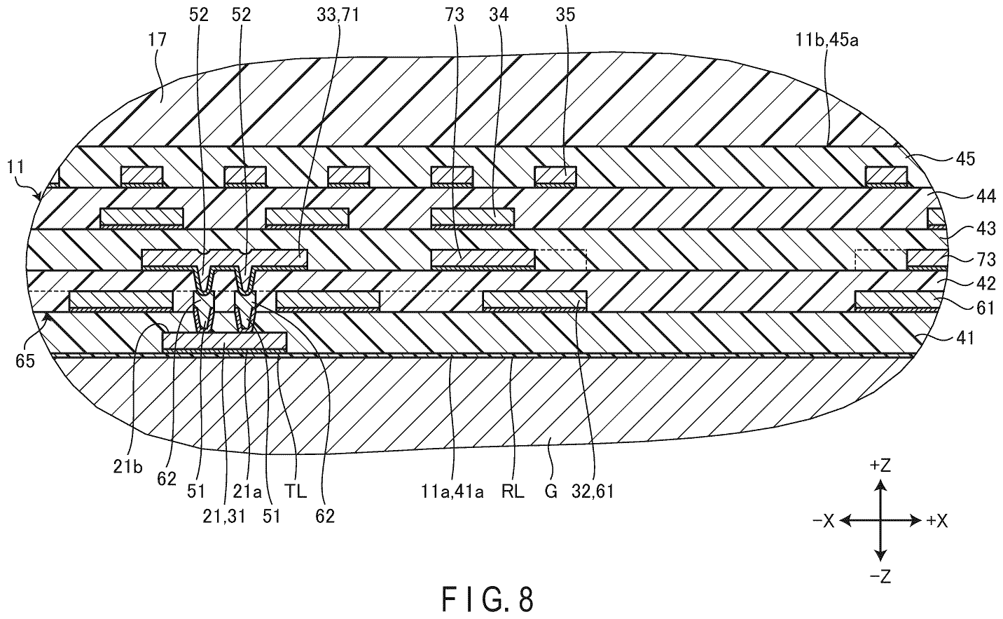

FIG. 8 is an exemplary sectional view schematically illustrating the interposers 11 sealed with the sealing resin 17 in the first embodiment. Next, the memory controller 12 and the flash memories 13 are mounted on each interposer 11. For example, the memory controller 12 is mounted on the interposer 11 by flip chip mounting. In addition, the plurality of spacers 14 are bonded to the interposer 11, and the plurality of flash memories 13 are bonded to the memory controller 12 and the spacers 14. Furthermore, the plurality of flash memories 13 are connected to the interposer 11 by wire bonding.

Next, as illustrated in FIG. 8, the memory controller 12, the flash memories 13, the spacers 14, the bonding films 15, and the bonding wires 16 are sealed with the sealing resin 17. The sealing resin 17 adheres to outer surfaces 11b of the interposers 11.

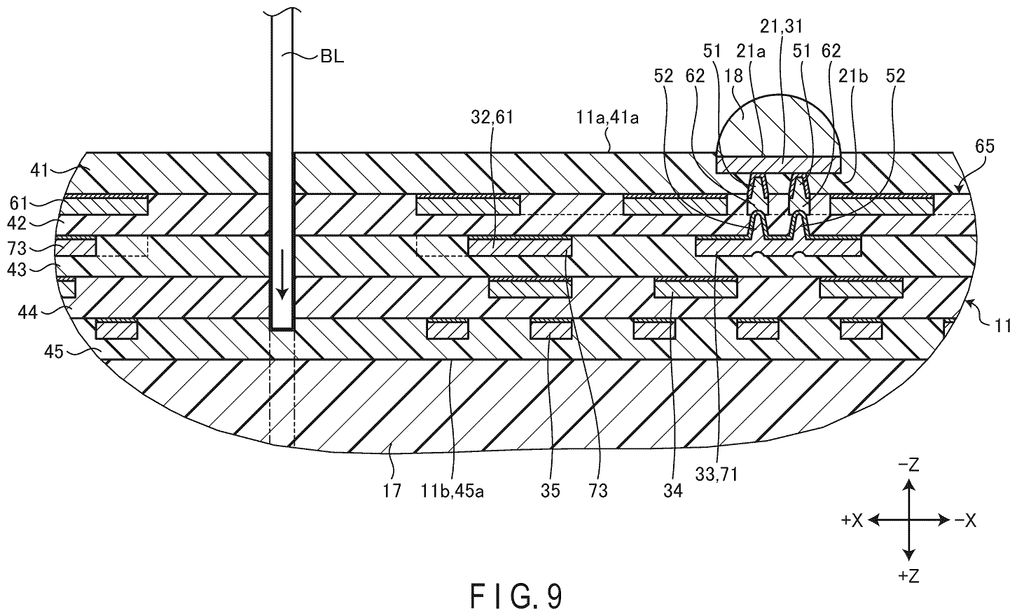

FIG. 9 is an exemplary sectional view schematically illustrating the semiconductor device 10 in the first embodiment that is to be diced. Next, the interposers 11 and the release layer RL are detached from the glass substrate G. Next, the release layer RL is removed from outer surfaces 11a of the interposers 11.

Next, titanium layers TL on the flat surfaces 21a of the pads 21 are removed by, for example, wet etching. Thus, the flat surfaces 21a of the pads 21, which are copper foils, are exposed. Next, the plurality of bumps 18 are provided on the plurality of pads 21.

In the above manner, a plurality of semiconductor devices 10 are integrally formed. Next, a blade BL divides the plurality of semiconductor devices 10 from one another. Thus, the manufacture of individual semiconductor devices 10 is completed.

The interposer 11 manufactured by using the RDL technology in the above manner includes thin conductive layers 31, 32, 33, 34, and 35 and thin insulating layers 41, 42, 43, 44, and 45. The conductive layers 31, 32, 33, 34, and 35 have a coefficient of thermal expansion different from that of the insulating layers 41, 42, 43, 44, and 45.

The difference in thermal expansion between the conductive layers 31, 32, 33, 34, and 35 and the insulating layers 41, 42, 43, 44, and 45 may cause stresses (in particular, thermal stresses) at, for example, the junctures (boundaries) of the edges 71a of the terminals 71 and the insulating layer 43.

In a typical RDL substrate, a thermal stress at the juncture of an edge of a pattern such as the terminals 71 and an insulating layer is likely to cause a crack at the juncture. Wires in the RDL substrate are thin and narrow, and thus the crack can result in wire breakage. In contrast, a crack is relatively unlikely to occur at a portion at which the juncture of the edge of a metallic mesh and an insulating layer overlaps the metallic mesh.

In the interposer 11 in the present embodiment, the mesh 61 covers the edges 71a of the terminals 71, the wires 72, and the edges 73a of the meshes 73. As a result, the mesh 61 reinforces the junctures of the edges 71a of the terminals 71 and the insulating layer 43, and thus it is possible to suppress a crack from occurring at the junctures. In addition, the mesh 61 reinforces the wires 72 that are formed by using the RDL technology to be thin and narrow, and thus it is possible to suppress the wire breakage of the wires 72.

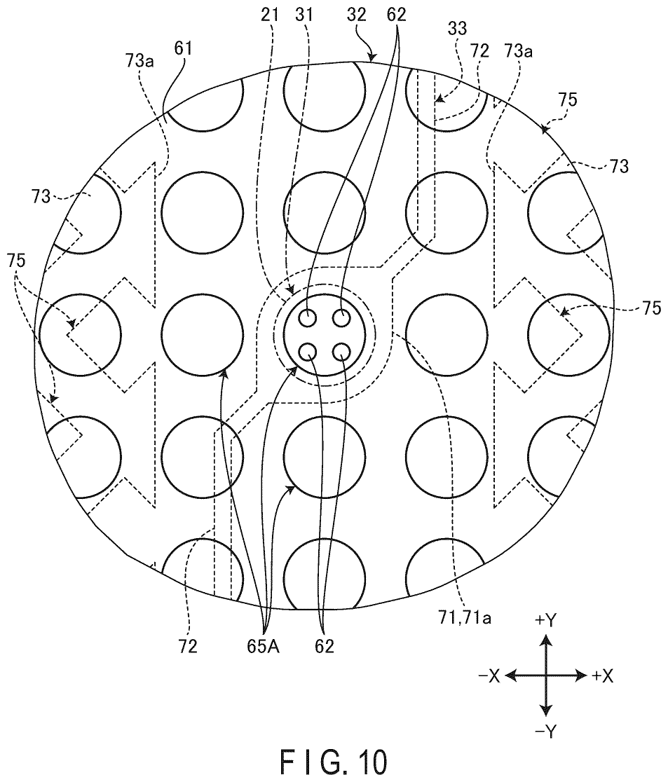

FIG. 10 is an exemplary plan view schematically illustrating three conductive layers 31, 32, and 33 according to a first modification of the first embodiment. As illustrated in FIG. 10, the mesh 61 may be provided with a plurality of holes 65A instead of the plurality of holes 65.

As illustrated in FIG. 3, two adjacent holes 65 of the plurality of holes 65 are adjacent to each other in a direction between the X direction and the Y direction (i.e., an oblique direction with respect to the X direction and the Y direction). That is, the plurality of holes 65 are disposed in, for example, a rhombic lattice or a hexagonal lattice.

In contrast, as illustrated in FIG. 10, two adjacent holes 65A of the plurality of holes 65A are adjacent to each other in the X direction or the Y direction. That is, the plurality of holes 65A are disposed in, for example, a square lattice or a rectangular lattice.

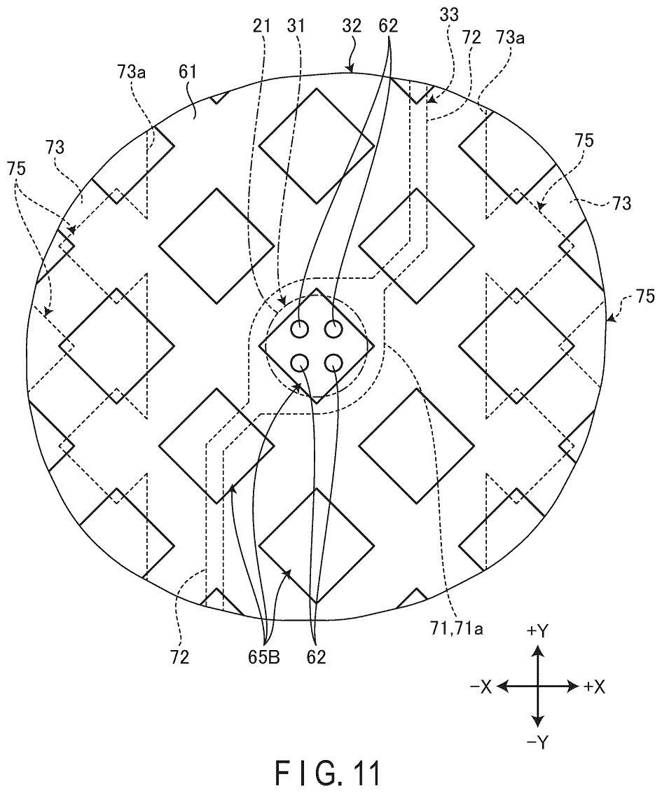

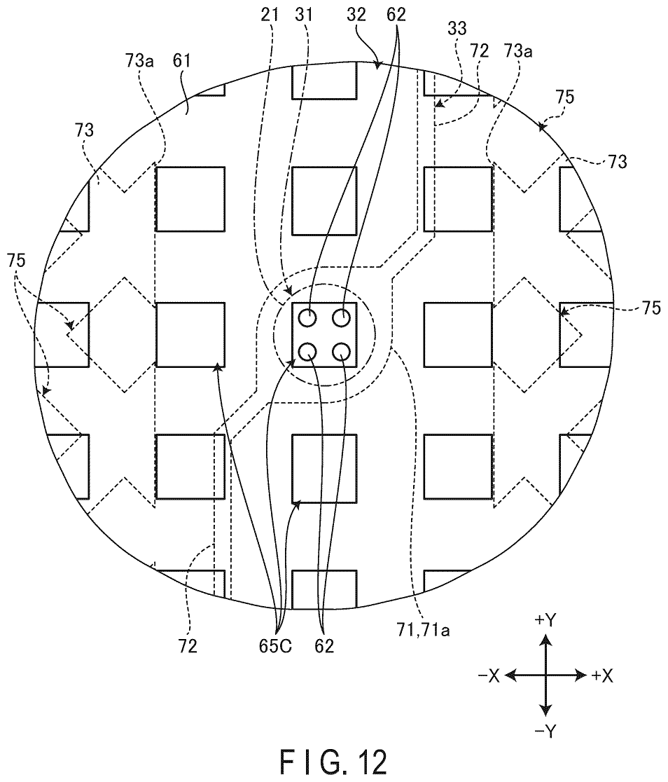

FIG. 11 is an exemplary plan view schematically illustrating three conductive layers 31, 32, and 33 according to a second modification of the first embodiment. FIG. 12 is an exemplary plan view schematically illustrating three conductive layers 31, 32, and 33 according to a third modification of the first embodiment.

As illustrated in FIG. 11, the mesh 61 may be provided with a plurality of holes 65B instead of the plurality of holes 65. Alternatively, as illustrated in FIG. 12, the mesh 61 may be provided with a plurality of holes 65C instead of the plurality of holes 65.

As illustrated in FIG. 3, each of the plurality of holes 65 is a circular hole. In contrast, as illustrated in FIG. 11 and FIG. 12, each of the pluralities of holes 65B and 65C is a quadrilateral hole. The plurality of holes 65B are disposed in a rhombic lattice or a hexagonal lattice. The plurality of holes 65C are disposed in a square lattice or a rectangular lattice.

As described above, the holes of the mesh 61 (the holes 65, 65A, 65B, 65C) may be in various shapes. The holes of the mesh 61 are not limited to the above examples. The holes may each be another polygon such as a hexagon or may each be another shape.

In the semiconductor device 10 according to the first embodiment described above, the interposer 11 includes the outer surface 11a, the outer surface 11b located on the opposite side to the outer surface 11a, and the pads 21 provided on the outer surface 11a. The interposer 11 includes the conductive layers 31, 32, 33, 34, and 35, the insulating layers 41, 42, 43, 44, and 45 each interposed between two adjacent layers of the conductive layers 31, 32, 33, 34, and 35, and the pluralities of vias 51 and 52 each connecting at least two layers of the conductive layers 31, 32, 33, 34, and 35. In the case where the number of the conductive layers 31, 32, 33, 34, and 35 is four, the distance between the outer surface 11a and the outer surface 11b is 50 μm or smaller. In the case where the number of the conductive layers 31, 32, 33, 34, and 35 is five, the distance between the outer surface 11a and the outer surface 11b is 60 μm. Such a thin interposer 11 can be manufactured by the RDL technology.

The conductive layers 31, 32, 33, 34, and 35 include the pads 21, the terminals 71, the wires 72, the meshes 73, and the mesh 61. The pads 21 are included in the conductive layer 31 of the conductive layers 31, 32, 33, 34, and 35. The terminals 71 are included in the conductive layer 33 of the conductive layers 31, 32, 33, 34, and 35 and connected to the pads 21 through at least one of the vias 51 and 52. The wires 72 are included in the conductive layer 33 and connected to the terminals 71. The meshes 73 are included in the conductive layer 33 and separated from the terminals 71 and the wires 72. The mesh 61 is included in the conductive layer 32 located between the conductive layer 31 and the conductive layer 33 of the conductive layers 31, 32, 33, 34, and 35. The mesh 61 is electrically isolated from the pads 21, the terminals 71, and the wires 72 and covers the terminals 71, the wires 72, and the meshes 73 at least partially as viewed in the Z direction, which is perpendicular to the outer surface 11a.

For example, in the interposer 11 manufactured by the RDL technology, the difference in thermal expansion between the conductive layers 31, 32, 33, 34, and 35 and the insulating layers 41, 42, 43, 44, and 45 can cause thermal stresses at the junctures of the edges 71a of the terminals 71 and the insulating layer 43. However, the mesh 61 that covers the terminals 71, the wires 72, and the meshes 73 reinforces the junctures of the edges 71a of the terminals 71 and the insulating layer 43. The mesh 61 also reinforces the junctures of the terminals 71 and the wires 72. Thus, the semiconductor device 10 can suppress a crack between an edge 71a of a terminal 71 and the insulating layer 43 from being caused by a thermal stress and can suppress a crack between a terminal 71 and a wire 72 from being caused by a thermal stress. That is, the semiconductor device 10 can suppress the wire breakage from being caused by a thermal stress.

The mesh 61 covers the pads 21 at least partially as viewed in the Z direction, which is perpendicular to the outer surface 11a. Thus, the mesh 61 reinforces the junctures of the pads 21 and the insulating layer 41. Thus, the semiconductor device 10 can suppress a crack between a pad 21 and the insulating layer 41 from being caused by a thermal stress.

The pads 21 include the flat surfaces 21a included in the outer surface 11a. The insulating layers 41, 42, 43, 44, and 45 are separated from the flat surfaces 21a. In other words, the insulating layers 41, 42, 43, 44, and 45 do not cover the flat surfaces 21a of the pads 21. Therefore, the semiconductor device 10 can suppress the interposer 11 from being increased in thickness by the covering of the flat surfaces 21a of the pads 21 by the insulating layers 41, 42, 43, 44, and 45.

The mesh 61 is included in the conductive layer 32. The conductive layer 32 includes the relay patterns 62 each located in one of the plurality of holes 65 of the mesh 61 and electrically isolated from the mesh 61. The vias 51 connect the pads 21 and the relay patterns 62. The vias 52 connect the terminals 71 and the relay patterns 62. The vias 51 and the vias 52 are arranged in the Z direction, which is perpendicular to the outer surface 11a. That is, the terminals 71 and the pads 21 are connected to each other with the stack vias SV1. In the semiconductor device 10, the connection between the terminals 71 and the pads 21 with the stack vias SV1 can make the holes 65 of the mesh 61 small.

In a projection in the Z direction, which is perpendicular to the outer surface 11a, each of the plurality of holes 65 of the mesh 61 is smaller than each of the terminals 71. Thus, in the semiconductor device 10, the terminals 71 can be made small, which can in turn increase the wiring density in the conductive layer 33.

### Second Embodiment

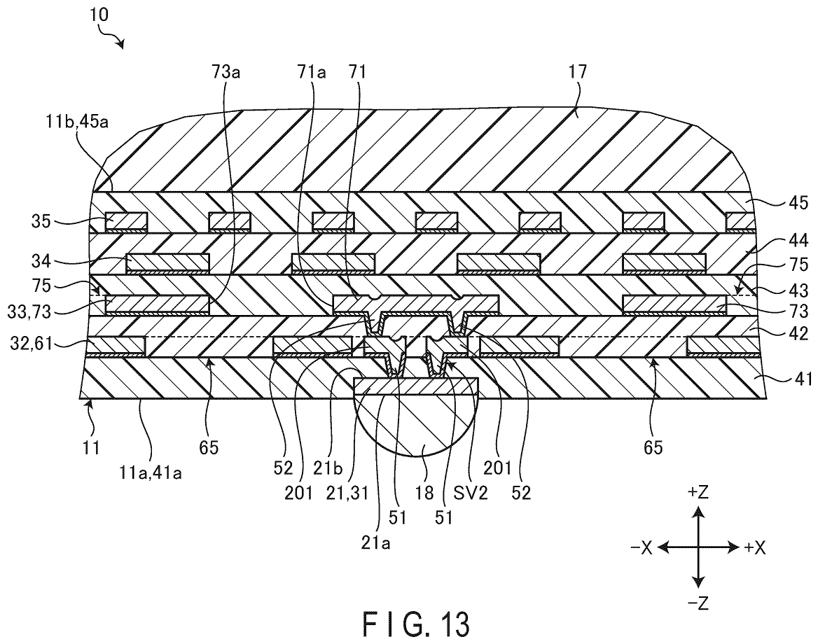

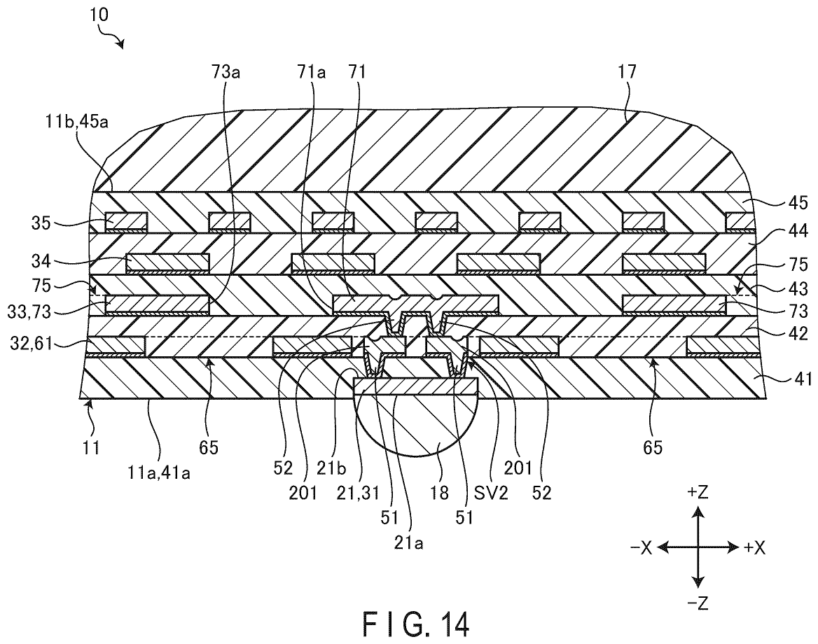

With reference to FIG. 13 and FIG. 14, a second embodiment will be described below. Note that, in the following description of multiple embodiments, the constituent elements having the same functions as previously described constituent elements are denoted by the same reference characters as those of the previously described constituent elements, and the description thereof may be omitted. Furthermore, a plurality of constituent elements denoted by the same reference numerals are not necessarily common in all of their functions and properties and may have different functions and properties according to the respective embodiments.

FIG. 13 is an exemplary sectional view schematically illustrating a part of a semiconductor device 10 according to the second embodiment. As illustrated in FIG. 13, a conductive layer 32 in the second embodiment includes a plurality of relay patterns 201 instead of the plurality of relay patterns 62. The relay patterns 201 are substantially equivalent to the relay patterns 62 except for the points described below.

The relay patterns 201 extend in a direction parallel to an outer surface 11a of an interposer 11. For example, the relay patterns 201 extend in the X direction. The relay patterns 201 may extend in the Y direction or in a direction between the X direction and the Y direction (i.e., an oblique direction with respect to the X direction and the Y direction).

Each of vias 51 is connected to one end portion of a corresponding one of the relay patterns 201 in the X direction. Each of vias 52 is connected to the other end portion of a corresponding one of the relay patterns 201 in the X direction. That is, one via 51 and one via 52 that are connected to one relay pattern 201 are separated from each other in the X direction. The vias 51 and 52 and the relay patterns 201 form staggered vias SV2. The staggered vias SV2 may have another pattern.

Every two staggered vias SV2 adjacent in the X direction are formed to be symmetric in the X direction. For example, two vias 52 are disposed outward of two vias 51. That is, the two vias 51 are located between the two vias 52 in the X direction.

FIG. 14 is an exemplary sectional view schematically illustrating a part of a semiconductor device 10 according to a modification of the second embodiment. As illustrated in FIG. 14, two vias 52 may be located between two vias 51 in the X direction. Note that a plurality of staggered vias SV2 may have the same shape or may have shapes different from one another.

In the semiconductor device 10 in the second embodiment described above, the vias 51 and the vias 52 are separated from each other in the X direction parallel to the outer surface 11a. That is, terminals 71 and pads 21 are connected to each other with the staggered vias SV2. The connection between the terminals 71 and the pads 21 with the staggered vias SV2 eliminates the need for filling the vias 51 and the vias 52, thus enabling the semiconductor device 10 to be easily manufactured.

### Third Embodiment

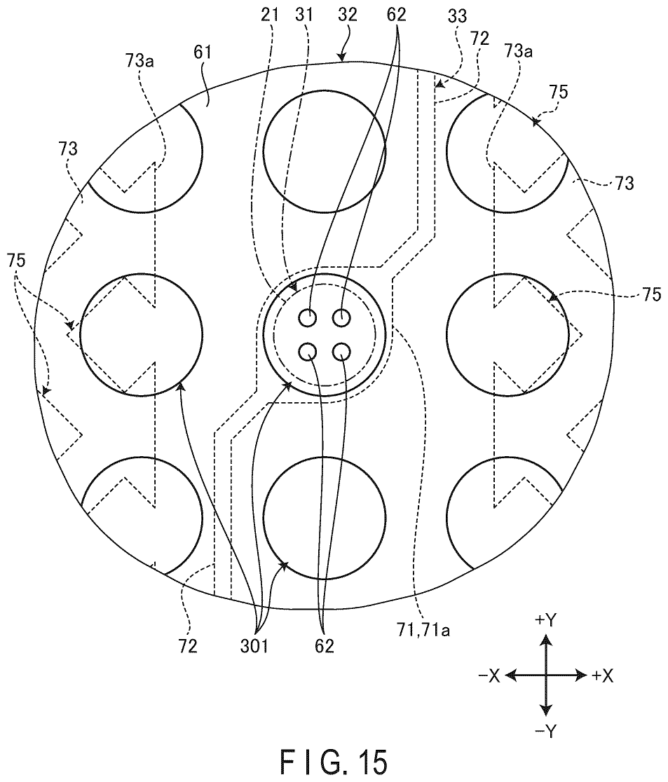

With reference to FIG. 15, a third embodiment will be described below. FIG. 15 is an exemplary plan view schematically illustrating three conductive layers 31, 32, and 33 according to the third embodiment. As illustrated in FIG. 15, a mesh 61 in the third embodiment is provided with a plurality of holes 301 instead of the plurality of holes 65. The holes 301 are substantially equivalent to the holes 65 except for the points described below.

In a projection in the Z direction such as FIG. 15, each of the plurality of holes 301 of the mesh 61 in the present embodiment is larger than each of a plurality of pads 21. The mesh 61 covers the plurality of pads 21 at least partially such that the plurality of pads 21 overlap the respective holes 301 as viewed in the Z direction.

In the semiconductor device 10 in the third embodiment described above, each of the plurality of holes 301 of the mesh 61 is larger than each of the pads 21 in a projection in the Z direction. The mesh 61 covers the pads 21 at least partially such that each of the pads 21 overlaps one of the plurality of holes 301 as viewed in the Z direction. That is, the pads 21 are not covered by metallic portions of the mesh 61. As a result, it is difficult for the mesh 61 to constrain the pads 21 when conductive layers 31, 32, 33, 34, and 35 and insulating layers 41, 42, 43, 44, and 45 thermally expand. Therefore, the mesh 61 can suppress thermal stresses at the junctures of the pads 21 and the insulating layer 41 from being increased by the constraint of the pads 21.

### Fourth Embodiment

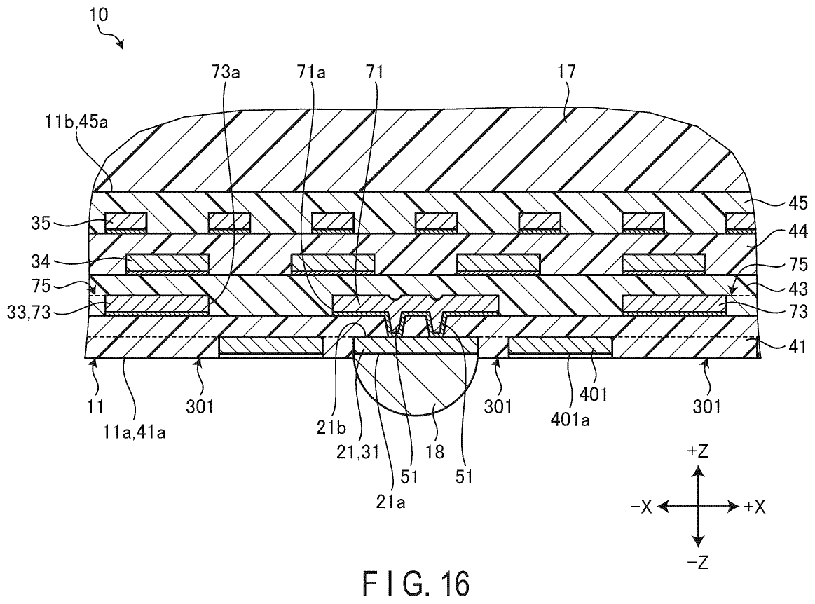

With reference to FIG. 16, a fourth embodiment will be described below. FIG. 16 is an exemplary sectional view schematically illustrating a part of a semiconductor device 10 according to the fourth embodiment. As illustrated in FIG. 16, an interposer 11 in the fourth embodiment does not include a conductive layer 32 and an insulating layer 42. That is, the interposer 11 includes four conductive layers 31, 33, 34, and 35, four insulating layers 41, 43, 44, and 45, and a plurality of vias 51. As a result, the interposer 11 has a thickness of 50 μm or smaller.

The insulating layer 41 in the fourth embodiment is interposed between two conductive layers 31 and 33. The plurality of vias 51 in the fourth embodiment connect the two conductive layers 31 and 33. In the fourth embodiment, each of the plurality of vias 51 connects one of a plurality of pads 21 and one of a plurality of terminals 71.

In the fourth embodiment, the conductive layer 31 includes a mesh 401. The mesh 401 is an example of the second mesh. The mesh 401 is substantially equivalent to the mesh 61 except for the points described below.

As in the third embodiment, the mesh 401 is provided with a plurality of holes 301. That is, in a projection in the Z direction, each of the plurality of holes 301 of the mesh 401 is larger than each of the plurality of pads 21. Each of the plurality of pads 21 is located in one of the plurality of holes 301. The pads 21 are separated from the mesh 401.

The mesh 401 has a flat surface 401a. The flat surface 401a forms a part of an outer surface 11a. That is, the flat surface 401a is included in the outer surface 11a. The flat surface 401a faces substantially in the −Z direction.

The insulating layers 41, 43, 44, and 45 of the interposer 11 in the fourth embodiment do not cover the flat surface 401a. That is, the flat surface 401a is separated from the insulating layers 41, 43, 44, and 45.

A surface 41a of the insulating layer 41 in the fourth embodiment projects from the flat surface 401a of the mesh 401 in the −Z direction because a titanium layer TL is removed in a manufacturing process. In other words, the flat surface 401a of the mesh 401 is recessed from the surface 41a of the insulating layer 41. Note that the flat surface 401a may be covered by the insulating layer 41 or another insulating layer.

In the semiconductor device 10 in the fourth embodiment described above, the mesh 401 is included in the conductive layer 31. That is, the interposer 11 dispenses with the need to provide a conductive layer 32 between the conductive layer 31 and the conductive layer 33. Therefore, in the semiconductor device 10, the interposer 11 can be made thin.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising
a substrate including a first outer surface, a second outer surface, and a pad, the second outer surface located on an opposite side of the substrate with respect to the first outer surface, the pad being provided on the first outer surface, wherein
the substrate includes at least four conductive layers, a plurality of insulating layers, and a plurality of vias, the plurality of insulating layers each being interposed between adjacent two of the conductive layers, the plurality of vias each connecting at least two of the conductive layers,
a distance between the first outer surface and the second outer surface is 60 μm or smaller, and
the conductive layers include:
the pad that is included in a first conductive layer of the conductive layers;
a terminal that is included in a second conductive layer of the conductive layers and is electrically connected to the pad through at least one of the vias;
a wire that is included in the second conductive layer and is electrically connected to the terminal;
a first mesh that is included in the second conductive layer and is electrically and physically separated from the terminal and the wire; and
a second mesh that is included in the first conductive layer or a third conductive layer of the conductive layers that is between the first conductive layer and the second conducive layer, is electrically isolated from the pad, the terminal, and the wire, and covers the terminal, the wire, and the first mesh at least partially when viewed in a direction perpendicular to the first outer surface.

2. The semiconductor device of claim 1, wherein
the pad includes a flat surface that is included in the first outer surface, and
none of the insulating layers covers the flat surface.

3. The semiconductor device of claim 1, wherein
the second mesh is included in the third conductive layer and has a plurality of holes,
the third conductive layer includes a relay pattern that is located in one of the plurality of holes of the second mesh and is electrically isolated from the second mesh,
the vias include a first via and a second via, the first via connecting the pad and the relay pattern, the second via connecting the terminal and the relay pattern.

4. The semiconductor device of claim 3, wherein the first via and the second via are aligned along the direction perpendicular to the first outer surface.

5. The semiconductor device of claim 3, wherein the first via and the second via are not aligned along the direction perpendicular to the first outer surface.

6. The semiconductor device of claim 3, wherein the plurality of holes are aligned in first and second directions that are perpendicular to each other and parallel to the first outer surface.

7. The semiconductor device of claim 6, wherein the substrate has a rectangular shape with edges that extend parallel to either the first direction or the second direction.

8. The semiconductor device of claim 6, wherein the substrate has a rectangular shape with edges that extend obliquely with respect to the first direction and the second direction.

9. The semiconductor device of claim 6, wherein the holes are circular and have the same diameter that is smaller than a diameter of the pad.

10. The semiconductor device of claim 6, wherein the holes are circular and have the same diameter that is larger than a diameter of the pad.

11. The semiconductor device of claim 6, wherein the holes are square.

12. The semiconductor device of claim 1, wherein in a projection in the direction perpendicular to the first outer surface, each of a plurality of holes of the second mesh has a smaller area than the terminal.

13. The semiconductor device of claim 1, wherein the second mesh is included in the first conductive layer.

14. The semiconductor device of claim 1, wherein the number of conductive layers is five.

15. The semiconductor device of claim 1, wherein the number of conductive layers is four and the distance between the first outer surface and the second outer surface is 50 μm or smaller.

16. A semiconductor device comprising
a substrate having a thickness of 60 μm or smaller, the substrate including a first outer surface and a second outer surface opposite to the first outer surface, wherein
the substrate includes at least four conductive layers, a plurality of insulating layers, and a plurality of vias, the plurality of insulating layers each being interposed between adjacent two of the conductive layers, the plurality of vias each connecting at least two of the conductive layers, and
the conductive layers include:
a first conductive layer including a pad having an outer surface that is exposed on the first outer surface of the substrate;
a second conductive layer including a terminal electrically connected to the pad through at least one of the vias, a wire electrically connected to the terminal, and a first mesh that is electrically and physically separated from the terminal and the wire;
a third conductive layer between the first conductive layer and the second conductive layer, the third conductive layer including a second mesh that is electrically isolated from the pad, the terminal, and the wire, and overlaps the terminal, the wire, and the first mesh at least partially in a direction perpendicular to the first outer surface.

17. The semiconductor device of claim 16, wherein the outer surface of the pad is recessed with respect to the outer surface of the substrate.

18. The semiconductor device of claim 16, wherein
the third conductive layer includes first and second relay patterns that are located in one of the plurality of holes of the second mesh and are electrically isolated from the second mesh, and
the vias include first and second vias electrically connected to the first relay pattern and third and fourth vias electrically connected to the second relay pattern.

19. The semiconductor device of claim 18, wherein
the first and second vias are aligned in the direction perpendicular to the first outer surface and the third and fourth vias are aligned in the direction perpendicular to the first outer surface.

20. The semiconductor device of claim 18, wherein
the first via is offset with respect to the second via in a first direction that is parallel to the first outer surface by a first distance, and the third via is offset with respect to the fourth via in a second direction that is parallel to the first outer surface and opposite to the first direction by a second distance that is equal to the first distance.
